(19) United States
(12) Patent Application Publication
(10) Pub. No.: US 2008/0182360 A1
(43) Pub. Date: Jul. 31, 2008

(54) Fabrication method of semiconductor package

(76) Inventors: Chi Chih Lin, Pingjhen City (TW); Bo Sun, Pingjhen City (TW); Hung Jen Wang, Gueishan Township (TW); Jen Feng Tseng, Jhongli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/907,137

(22) Filed: Oct. 10, 2007

(30) Foreign Application Priority Data
Jan. 26, 2007 (TW) 96102973

(51) Int. Cl. H01L 21/60

(52) U.S. Cl. 438/108; 257/E21.511

(57) ABSTRACT

A fabrication method of a semiconductor package is applied to fabricate the package with the lead frame. The fabrication method includes: performing a surface treatment on a carrier; electroplating a plurality of metal-stacked layers on the surface of the carrier, wherein the top of the metal-stacked layer is a bonding surface and the bottom of the metal-stacked layer is a welding surface; performing a chip bonding step; forming a molding compound on the carrier; removing the carrier and performing a dicing step to form a plurality of semiconductor packages. The fabrication method of a semiconductor package also includes that forming a plurality of cavities on the carrier surface, electroplating the metal-stacked layer on the cavities, and then performing the chip bonding step, forming the molding compound on the carrier; remove the carrier and performing the dicing step. Using the foregoing steps can prevent the overflow situation without using any tape.

### BACKGROUND OF THE INVENTION

1. Field of the Invention

The present invention relates to a fabrication method of a semiconductor package, and, more especially, to the fabrication method of the semiconductor package with a lead frame structure.

2. Background of the Related Art

In the traditional package processes, a tape is required to arrange on the SMT mounting surface of the lead frame before proceeding the molding process, in order to prevent the molding flow over to the SMT pads and affect the follow-up manufacturing process. However, the tape will remain the viscose on the SMT mounting surface to pollute the SMT pads. Besides, the processes of mounting the tape, removing the tape and purging the viscose will increase the fabrication cost and decrease the yield. Therefore, how to prevent the molding flow over to the SMT mounting surface without using any taps is a characteristic of the present invention.

On the other hand, during the traditional package processes, a tin-plating process is required to applied on the SMT mounting surface after moving the tape, in order to proceeding the following SMT manufacturing process. But the tin-plating process does not satisfy the unleaded demand of the restriction of the use of certain hazardous substrate in EEE (ROHS). Beside, the row material of the traditional lead frame is the copper plate or the iron plate having the established thickness, so that the manufacturing scale of the lead frame will be limited, such that it is hard to reduce the height of whole package effectively.

### SUMMARY OF THE INVENTION

In order to solve the foregoing problems, one object of this invention is to provide a fabrication method of a semiconductor package without using any tape, so that the conventional processes of mounting the tape, removing the tape and purging the viscose will be abridged, to have the advantages of decreasing the fabrication cost and raising the yield.

One object of this invention is to provide a fabrication method of the semiconductor package, wherein the bonding surface of the metal-stack layer is made of the soldering material, so that the bonding surface can be directly used in the following SMT manufacturing process without doing any tin-plating process, so as to reduce the fabrication cost, raise the yield and satisfy the unleaded demand of ROHS.

One object of this invention is to provide a fabrication method of the semiconductor package, wherein the thickness of the metal-stacked layers can be changed according to the demand to construct different lead frame structures with different thicknesses, so as to improve the conventional defect, wherein the scale of the lead frame is limited due to the row material, such as the copper plate or the iron plate, which have the established thickness

One object of this invention is to provide a fabrication method of the semiconductor package, wherein the thickness of the metal-stacked layers can be controlled in very thin, not only to reduce the height of whole package, but also to provide a suitable thickness for the lead frame structure to proceed the following package process by using the existed equipment, so as to have the advantages of reducing the additional expenditure on equipment to promote the competitiveness.

Accordingly, one embodiment of the present invention provides a fabrication method of a semiconductor package, which includes: providing a carrier having a first surface and a second surface; performing a surface treatment on the first surface; covering a patterned insulating layer on the first surface and covering an insulating layer on the second surface, wherein the patterned insulating layer has a plurality of openings to expose portions of the first surface; forming a plurality of metal-stacked layers on the exposed first surface, wherein every metal-stack layer at least includes a bonding surface and a welding surface; and removing the patterned insulating layer and the insulating layer to construct a lead frame structure; performing a chip bonding step; forming a molding compound on the carrier; removing the carrier; and performing a dicing step to form a plurality of semiconductor packages.

Another embodiment of the present invention provides a fabrication method of a semiconductor package, which includes: providing a carrier having a first surface and a second surface; performing a surface treatment on the first surface; forming a plurality cavities on the first surface; and depositing a plurality of metal-stacked layers on the cavities respectively to construct a lead frame structure, wherein every metal-stack layer includes at least a bonding surface and a welding surface; performing a chip bonding step; forming a molding compound on the carrier; removing the carrier to make the metal-stack layers stick out of the molding compound; and performing a dicing step to form a plurality of semiconductor packages.

### BRIEF DESCRIPTION OF THE DRAWINGS

FIG. 1a to FIG. 1i are cross-sectional diagrams illustrating the fabrication method of a semiconductor package in accordance with an embodiment of the present invention;

FIG. 2 is a cross-sectional diagram illustrating the structure of a semiconductor package in accordance with another embodiment of the present invention;

FIG. 3a to FIG. 3f are cross-sectional diagrams illustrating the chip bonding steps in accordance with another embodiment of the present invention;

FIG. 4 is a cross-sectional diagram illustrating the structure of a semiconductor package in accordance with another embodiment of the present invention;

FIG. 5 is a cross-sectional diagram illustrating the structure of a semiconductor package in accordance with another embodiment of the present invention;

FIG. 6a to FIG. 6c are cross-sectional diagrams illustrating the fabrication method of a lead frame structure in accordance with another embodiment of the present invention;

FIG. 7 is a cross-sectional diagram illustrating the structure of a semiconductor package in accordance with another embodiment of the present invention;

FIG. 8 is a cross-sectional diagram illustrating the structure of a semiconductor package in accordance with another embodiment of the present invention; and

FIG. 9 is a cross-sectional diagram illustrating the structure of a semiconductor package in accordance with another embodiment of the present invention.

### DETAILED DESCRIPTION OF THE INVENTION

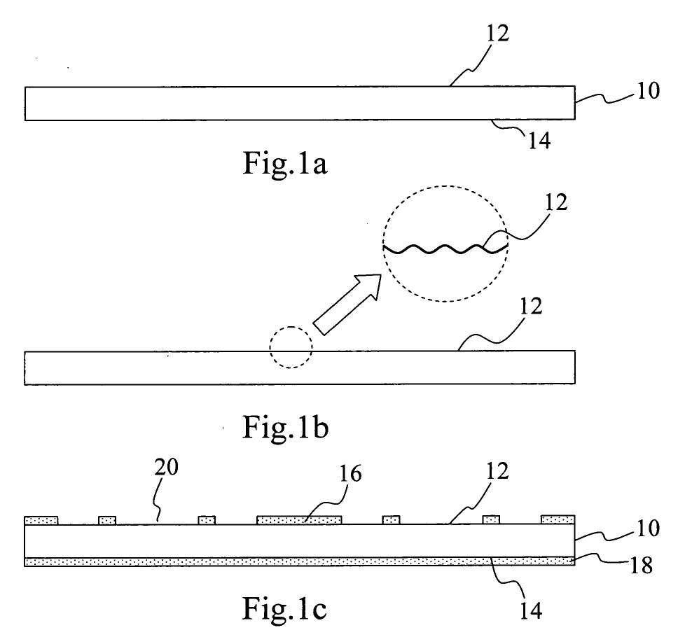

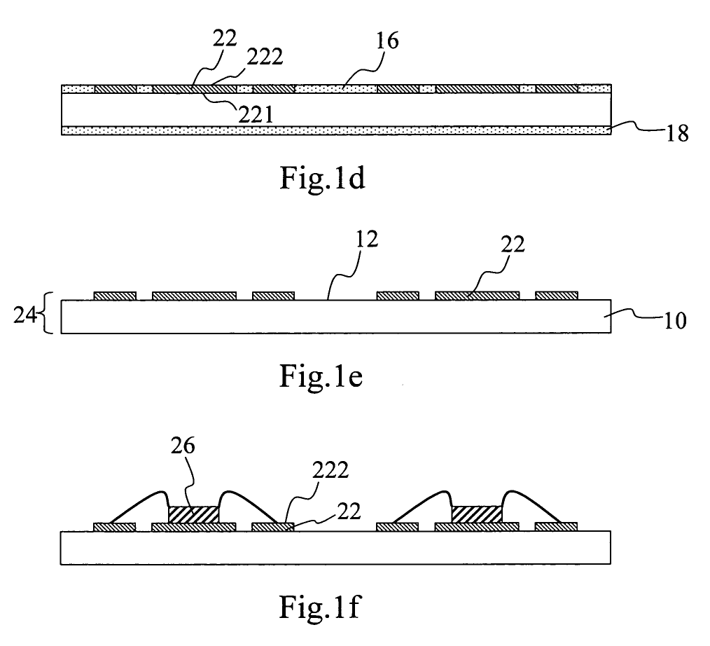

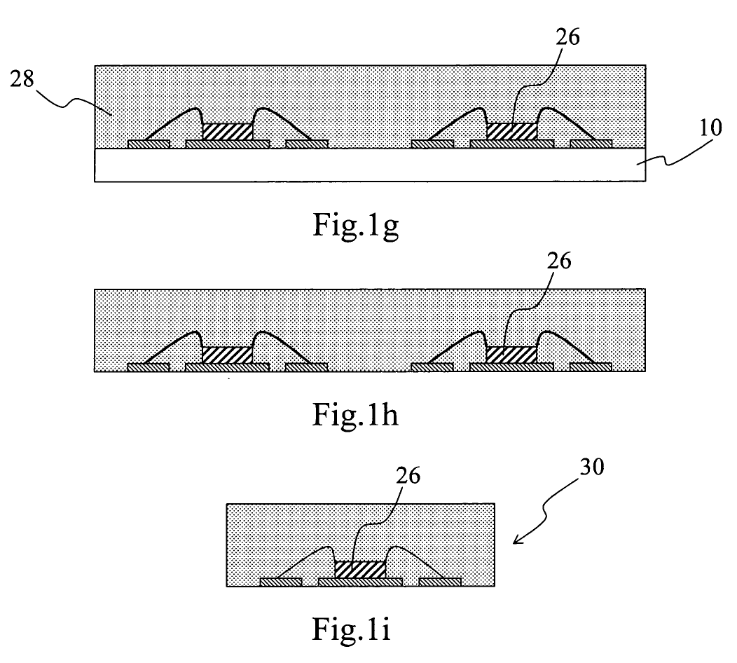

FIG. 1a to FIG. 1i are cross-sectional diagrams illustrating the fabrication method of a semiconductor package in accordance with an embodiment of the present invention. First, as shown in FIG. 1a, a carrier 10 is provided. The carrier 10 has a first surface 12 and a second surface 14, and the material of the carrier 10 is metal. A special surface treatment is performed to the first surface 12 to form the rough structure or the reticular structure on the first surface 12, as shown in FIG. 1b, which includes a partial enlarged diagram of the surface 12 in FIG. 1a. Please refer to FIG. 1c, a patterned insulating layer 16 covers the first surface 12 and an insulating layer 18 covers the second surface 14. A plurality of the openings 20 are formed on the patterned insulating layer 16 according to the chip-mounted positions and the circuit design, to expose portions of the first surface 12. Next, a plurality of metal-stack layers 22 are respectively disposed in the plurality of the openings 20, as shown in FIG. 1d, and every metal-stack layer 22 includes a bonding surface 221 on the bottom and a welding surface 222 on the top of the metal-stack layer 22, wherein the bonding surface 221 is made of the soldering material, such as the gold (Au), silver (Ag), palladium (Pd), nickel (Ni), copper (Cu) or tin (Sn), and the welding surface 222 is made of the material, such as the gold (Au), silver (Ag), tin (Sn), copper (Cu) or palladium (Pd) ,which are suitable for wire bonding or ball mounting. Later, the patterned insulating layer 16 and the insulating layer 18 are removed to construct a lead frame structure 24 as shown in FIG. 1e. Accordingly, the lead frame structure 24 includes the carrier 10 and the plurality of metal-stack layers 22 on the first surface 12. Next, a chip bonding step is performed, as shown in FIG. 1f, in which a plurality of chips 26 are electrically connected to the welding surfaces 222 of the metal-stack layers 22, respectively by the wire bonding technique, and then a molding compound 28 is formed on the carrier 10, as shown in FIG. 1g, to cover the chips 26 and the plurality of metal-stack layers 22. Finally, as shown in FIG. 1h, the carrier 10 is removed, and a dicing step is performed to form a plurality of semiconductor packages 30, wherein one of the semiconductor packages 30 is shown in FIG. 1i.

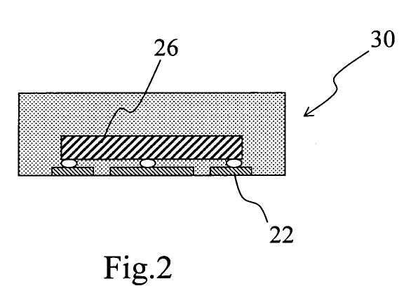

Furthermore, the patterned insulating layer 16 is formed on and covers the first surface 12 by the image transfer process, the printing process or the laser direct imaging process. In another embodiment, the chips 26 are electrically connected to the metal-stack layers 22 by the flip chip technique, and the constructed semiconductor package 30 is shown in FIG. 2.

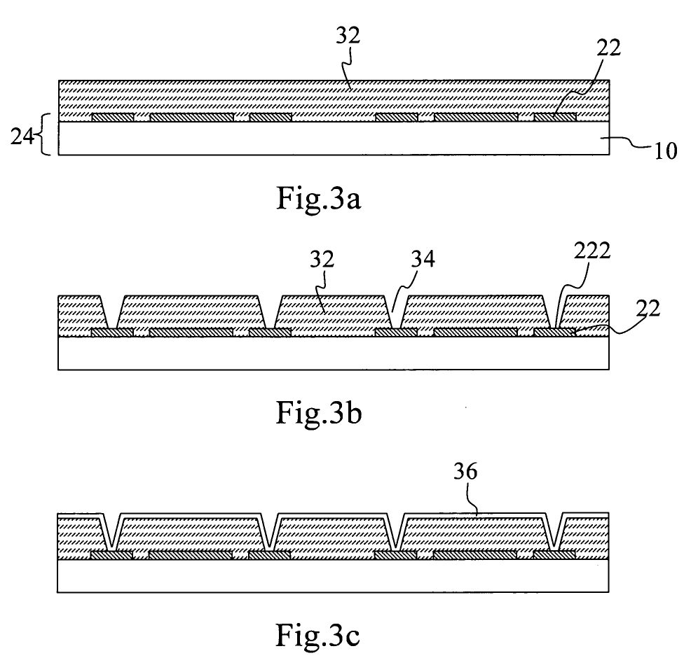

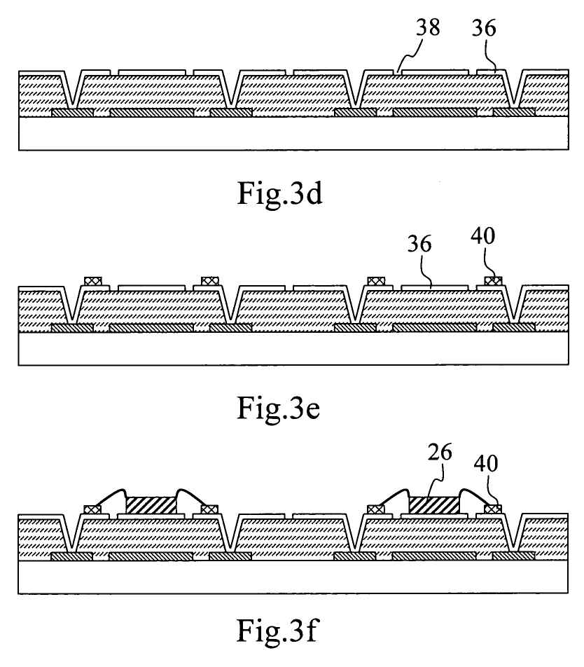

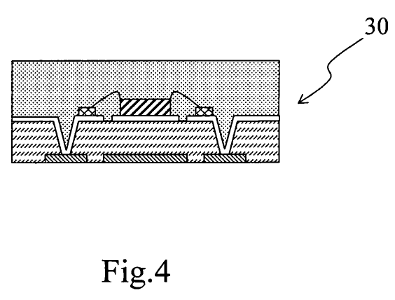

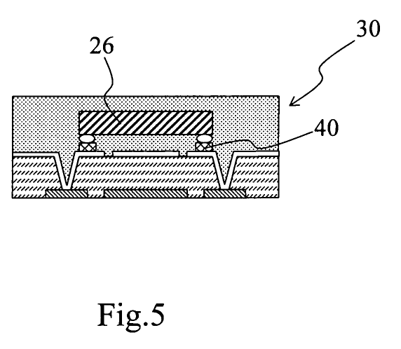

In another embodiment, after the lead frame structure 24 is constructed, the chip bonding step may include the following processes as shown in FIG. 3a to FIG. 3f. Referring to FIG. 3a, an insulating partition layer 32 is formed on the carrier 10 by coating, laminating or stamping to cover the metal-stack layers 22. As shown in FIG. 3b, a plurality of through holes 34 are formed on the insulating partition layer 32 by laser ablation, blind drilling, plasma or developing technique to expose portions of the welding surface 222 of a portion of the metal-stack layer 22. Next, as shown in FIG. 3c, a conductive layer 36 is formed for covering the surface of the insulating partition layer 32, the side walls of the through holes 34 and the exposed welding surface 222, wherein the conductive layer 36 is a copper plating layer in the present embodiment. Next, please refer to FIG. 3d and FIG. 3e, a patterned trace 38 is formed on the conductive layer 36 according to the circuit design, and a plurality of conducting pads 40 are arranged on the conductive layer 36 for performing the wire bonding process, and, as shown in FIG. 3f, the chips 26 are electrically connected to the conducting pads 40. Continuously, the steps of forming the molding compound, removing the carrier and dicing are performed to construct a semiconductor package 30 as shown in FIG. 4. In another embodiment, please refer to FIG. 5, the wire bonding process can be replaced by the flip chip technique to electrically connect the chips 26 with the conducting pads 40 to construct a semiconductor package 30 as shown in FIG. 5.

In the present invention, the metal-stack layers are formed on the carrier by electroplating, sputtering, evaporation or electroless plating, wherein the bonding surfaces of the metal-stack layers are combined with the gaps from the rough structure or the reticular structure, or the atoms of the bonding surfaces are filled in the gaps between the atoms of the carrier, so that the metal-stack layers are connected with the carrier by the physical bonding strength from the electroplating process. Therefore, the metal-stack layers will combine with the carrier without using any adhesion material. Because the gaps between the atoms of the carrier and the atoms of the bonding surfaces are very small, the other atoms, which are bigger than the atoms of the carrier and the bonding surfaces, can not permeate into the gap to form the intercept effect. It will prevent the following macromolecular compounds of the molding compound from permeating to the mounting surface between the carrier and the bonding surfaces, and avoid the macromolecular compounds polluting the mounting surface. Therefore, the present invention can abridge the processes of mounting the tape, removing the tape and purging the viscose to have the advantage of decreasing the fabrication cost. On the other hand, because the bonding surface of the metal-stack layer is made of the soldering material, so that the bonding surface can directly be used to the following SMT manufacturing process without doing any tin-plating process, so as to reduce the fabrication cost, raise the yield and satisfy the unleaded demand of ROHS.

Accordingly, the metal-stack layer further includes a middle layer between the bonding surface and the welding surface, and the material of the middle layer is nickel (Ni), palladium (Pd), silver (Ag), copper (Cu) or combinations thereof. Therefore, the whole metal-stack layer may be one of the following stack structures including: Au—Ni—Au, Au—Pd—Ni—Pd—Au, Au—Ni—Pd—Au, Au—Pd—Ni—Au, Ag—Ni—Pd—Au, Au—Pd—Ni—Ag, Ag—Ni—Au, Au—Ni—Ag, Ag—Ni—Ag, Pd—Ag—Ni—Ag, Pd—Ag—Ni—Ag—Pd, Au—Ni—Ag—Pd, Pd—Ag—Ni—Au, Pd—Ag—Ni—Sn, Ag—Ni—Sn, Au—Ni—Sn, Ag—Pd—Ni—Sn, Au—Ni—Cu—Ni—Au, Au—Pd—Ni—Cu—Ni—Pd—Au, Au—Ni—Cu—Ni—Pd—Au, Au—Pd—Ni—Cu—Ni—Au, Ag—Ni—Cu—Ni—Pd—Au, Au—Pd—Ni—Cu—Ni—Ag, Ag—Ni—Cu—Ni—Au, Au—Ni—Cu—Ni—Ag, Ag—Ni—Cu—Ni—Ag, Pd—Ag—Ni—Cu—Ni—Ag, Pd—Ag—Ni—Cu—Ni—Ag—Pd, Au—Ni—Cu—Ni—Ag—Pd, Pd—Ag—Ni—Cu—Ni—Au, Pd—Ag—Ni—Cu—Ni—Sn, Ag—Ni—Cu—Ni—Sn, Au—Ni—Cu—Ni—Sn, Au—Pd—Ni—Cu—Ni—Sn, Pd—Ag—Ni—Cu—Sn, Ag—Ni—Cu—Sn, Au—Ni—Cu—Sn, Ag—Pd—Ni—Cu—Sn, and Ag.

In the present invention, the thickness of the metal-stacked layers can be changed according to the demand of constructing different lead frame structures with different thicknesses. It can improve the conventional defect that the scale of the lead frame is limited due to the row material, such as the copper plate or the iron plate, which have the established thickness. Furthermore, the thickness of the metal-stacked layers can be controlled in very thin to reduce the height of whole package. Besides, the thickness of the lead frame structure can be manufactured to satisfy the following package process, so that the package can be manufactured by using the existed equipment but has the advantages of reducing the additional expenditure on equipment to raise the competitiveness.

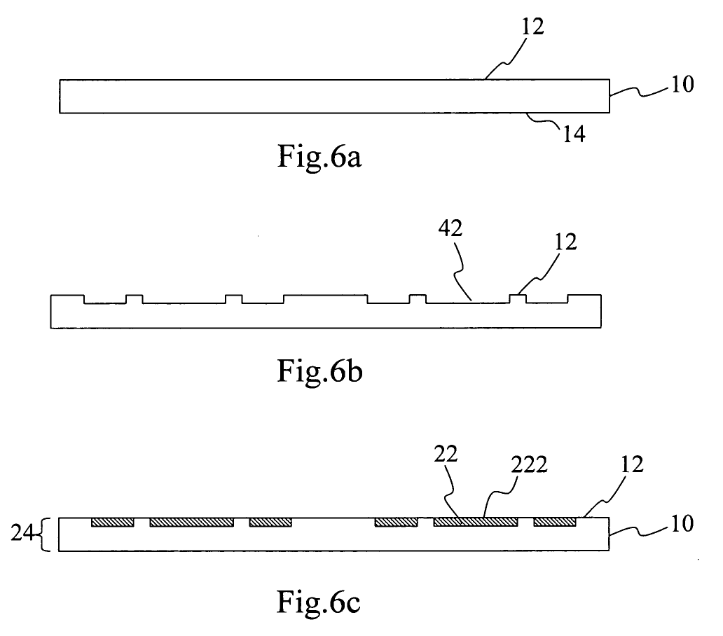

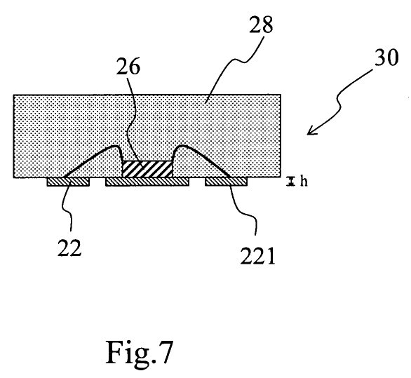

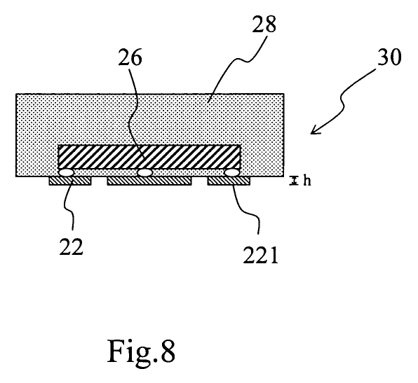

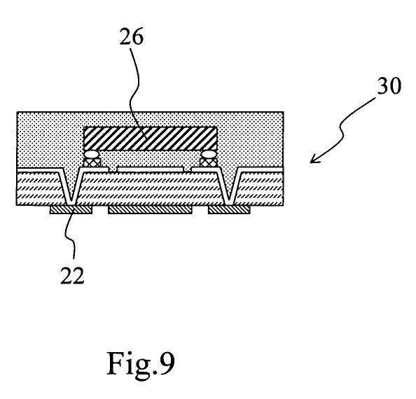

In the foregoing embodiment, the lead frame structure includes the carrier and the metal-stacked layers on the surface of the carrier. The lead frame structure according to another embodiment is disclosed, and the fabrication method is shown in FIG. 6a to FIG. 6c. First, as shown in FIG. 6a, a carrier 10 is provided, and the carrier 10 has a first surface 12 and a second surface 14 and is made of a metal. Next, as shown in FIG. 6b, a plurality of cavities 42 are formed on the first surface 12 by etching, depth control, electro etching or punching, and a surface treatment is performed on the surface of the cavities 42. Then, a plurality of metal-stack layers 22 are respectively disposed in the cavities 42 to construct a lead frame structure 24 as shown in FIG. 6c. Accordingly, the welding surfaces 222 of the metal-stack layers 22 and the first surface 12 can be made coplanar or not. The structure and material of the metal-stack layer 22 have been illustrated in the foregoing embodiment, and it will not be described repeatedly. The abovementioned steps of chip bonding, forming the molding compound, removing the carrier and dicing are performed on this lead frame structure 24 to construct a semiconductor package 30 shown in FIG. 7. The wire bonding process is employed for electrically connecting the chip to the metal-stack layers 22, but not limited. In another chip bonding process, the flip chip technique is used to electrically connect the chip 26 to the metal-stack layers 22, and the constructed semiconductor package 30 is shown in FIG. 8. Besides, the chip bonding steps as shown in FIG. 3a to FIG. 3f also can be used to mount the chip, and the constructed semiconductor package 30 is shown in FIG. 9.

Continuously, because the metal-stack layers are arranged in the cavities, the molding compound will not flow into the intervals among the metal-stack layers, so that a height difference (h) will exist between the molding compound and the bonding surface of the metal-stack layer. Please refer to FIG. 7 and FIG. 8, after the carrier is removed and the dicing step is performed, the height difference (h) between the bonding surface 221 and molding compound 28 will be helpful to increase the soldering reliability during the SMT manufacturing process. Therefore, in the present invention, the conventional processes of mounting the tape, removing the tape and purging the viscose will be abridged to have the advantages of decreasing the fabrication cost, raising the yield, satisfying the unleaded demand of ROHS, reducing the height of whole package and raising the product reliability.

Although the present invention has been explained in relation to its preferred embodiment, it is to be understood that other modifications and variation can be made without departing the spirit and scope of the invention as hereafter claimed.

What is claimed is:

1. A fabrication method of a semiconductor package, comprising:
fabricating a lead frame structure, comprising:
providing a carrier having a first surface and a second surface;
performing a surface treatment on said first surface;
covering a patterned insulating layer on said first surface and covering an insulating layer on said second surface, wherein said patterned insulating layer has a plurality of openings to expose portions of said first surface;
forming a plurality of metal-stacked layers on said exposed portions of said first surface, wherein every said metal-stack layer at least comprises a bonding surface and a welding surface; and
removing said patterned insulating layer and said insulating layer;
performing a chip bonding step to bond at least a chip on welding surface;
forming a molding compound on said first surface of said carrier;
removing said carrier; and
performing a dicing step to form a plurality of semiconductor packages.

2. The fabrication method of the semiconductor package according to claim 1, wherein the step of performing said surface treatment is to form a rough structure or a reticular structure on said first surface.

3. The fabrication method of the semiconductor package according to claim 1, wherein the step of covering said patterned insulating layer and said insulating layer is an image transfer process, a printing process or a laser direct imaging process.

4. The fabrication method of the semiconductor package according to claim 1, wherein the step of forming said plurality of metal-stack layers is implemented by electroplating, sputtering, evaporation or electroless plating.

5. The fabrication method of the semiconductor package according to claim 1, wherein the material of said welding surface is gold, silver, tin, copper or palladium, and the material of said bonding surface is gold, silver, palladium, nickel, copper or tin.

6. The fabrication method of the semiconductor package according to claim 1, wherein said metal-stack layer further comprises a middle layer between said bonding surface and said welding surface, and said middle layer is made of nickel, palladium, silver, copper or combinations thereof.

7. The fabrication method of the semiconductor package according to claim 1, wherein said chip bonding step comprises:
disposing at least one said chip on said welding surface; and
electrically connecting said chip to said welding surface.

8. The fabrication method of the semiconductor package according to claim 7, wherein the step of electrically connecting said chip is a wire bonding technique or a flip chip technique.

9. The fabrication method of the semiconductor package according to claim 1, wherein said chip bonding step comprises:
forming an insulating partition layer on said carrier to cover said metal-stack layer;
forming a plurality of through holes on said insulating partition layer to expose portions of said welding surface of a portion of said metal-stack layer;
forming a conductive layer on the surface of said insulating partition layer, the side walls of said through holes and said exposing portions of said welding surface;
forming a patterned trace on said conductive layer; and
disposing at least one said chip on said conductive layer and electrically connecting said chip to said conductive layer.

10. The fabrication method of the semiconductor package according to claim 9, wherein the step of electrically connecting said chip to said conductive layer is a wire bonding technique or a flip chip technique.

11. The fabrication method of the semiconductor package according to claim 9, wherein the step of forming said insulating partition layer is implemented by coating, laminating or stamping.

12. The fabrication method of the semiconductor package according to claim 9, wherein the step of forming said through holes is implemented by laser ablation, blind drill, plasma or developing technique.

13. The fabrication method of the semiconductor package according to claim 9, said conductive layer is a copper plating layer.

14. A fabrication method of a semiconductor package, comprising:
fabricating a lead frame structure, comprising:
providing a carrier having a first surface and a second surface;
performing a surface treatment on said first surface;
forming a plurality cavities on said first surface; and
depositing a plurality of metal-stacked layers on said cavities, respectively, wherein every said metal-stack layer at least comprises a bonding surface and a welding surface;
performing a chip bonding step to bonds at least one chip of said carrier;
forming a molding compound on said first surface of said carrier;
removing said carrier to make said metal-stack layers stick out of said molding compound; and
performing a dicing step to form a plurality of semiconductor packages.

15. The fabrication method of the semiconductor package according to claim 14, wherein the step of performing said surface treatment forms a rough structure or a reticular structure on said first surface.

16. The fabrication method of the semiconductor package according to claim 14, wherein the step of forming said cavities is implemented by etching, depth control, electro etching or punching.

17. The fabrication method of the semiconductor package according to claim 14, wherein the step of forming said metal-stack layers on said cavities is implemented by electroplating, sputtering, evaporation or electroless plating.

18. The fabrication method of the semiconductor package according to claim 14, wherein the material of said welding surface is gold, silver, tin, copper or palladium, and the material of said bonding surface is gold, silver, palladium, nickel, copper or tin.

19. The fabrication method of the semiconductor package according to claim 14, wherein said metal-stack layer further comprises a middle layer between said bonding surface and said welding surface, and said middle layer is made of nickel, palladium, silver, copper or combination thereof.

20. The fabrication method of the semiconductor package according to claim 14, wherein said chip bonding step comprises:
disposing at least one said chip on said welding surface; and
electrically connecting said chip to said welding surface.

21. The fabrication method of the semiconductor package according to claim 20, wherein the step of electrically connecting said chip to said welding surface is a wire bonding technique or flip chip technique.

22. The fabrication method of the semiconductor package according to claim 14, wherein said chip bonding step comprises:
forming an insulating partition layer on said carrier;
forming a plurality of through holes on said insulating partition layer to expose portions of said welding surface of a portion of said metal-stack layer;
forming a conductive layer on the surface of said insulating partition layer, the side walls of said through holes and said exposing portions of said welding surface;
forming a patterned trace on said conductive layer; and
disposing at least one said chip on said conductive layer and electrically connecting said chip to said conductive layer.

23. The fabrication method of the semiconductor package according to claim 22, wherein the step of electrically connecting to said conductive layer is a wire bonding technique or flip chip technique.

24. The fabrication method of the semiconductor package according to claim 22, wherein the step of forming said insulating partition layer is implemented by coating, laminating or stamping.

25. The fabrication method of the semiconductor package according to claim 22, wherein the step of forming said through holes is a laser ablation, blind drill, plasma or developing technique.
